(19) United States
(12) Patent Application Publication
(10) Pub. No.: US 2024/0161688 A1
(43) Pub. Date: May 16, 2024

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventors: Yanfen NIU, Wuhan, Hubei (CN); Xiaoxia ZHANG, Wuhan, Hubei (CN)

(73) Assignee: Wuhan China Star Optoelectronics Semiconductor Display Technology Co., Ltd., Wuhan, Hubei (CN)

(21) Appl. No.: 17/781,004

(22) PCT Filed: May 20, 2022
(86) PCT No.: PCT/CN2022/094216

§ 371 Date: May 30, 2022

(30) Foreign Application Priority Data
Apr. 26, 2022 (CN) 202210449176.X

(51) Int. Cl. G09G 3/3225; H10K 59/131

(52) U.S. Cl. CPC G09G 3/3225; H10K 59/131; G09G 2300/0408; G09G 2300/0842; G09G 2320/0233

(57) ABSTRACT

A display panel and a display device are disclosed. A first bending part is provided in a middle part of one of first connection parts in the display panel, so that a length of each of the first connection parts can be increased as much as possible within a unit area. As a result, a distribution area of the first connection parts is increased, thereby helping to reduce an amount of light transmission of the display panel. This avoids issues of light leakage and grating effect, thereby improving a display uniformity of the display panel, which is beneficial to improve a display performance.

### FIELD OF THE DISCLOSURE

The present application relates to the technical field of display devices, and more particularly, to a display panel and a display device.

### BACKGROUND

AMOLED display technology is an emerging panel technology. It has advantages of low power consumption, low cost, wide color gamut, high resolution, and high color saturation, etc., as well as characteristics of being bendable, easy to change shape and portable. It is recognized by the industry as the display technology with the most development potential.

In the display panel, it is usually necessary to set signal lines for providing signals to sub-pixels. The signal line is connected to a driving switch through a connection line. However, for a high-resolution AMOLED display device, when the same power supply voltage is used to supply power to each pixel unit in a display area, a wiring method of the connection lines is not ideal, resulting in a large light-transmitting area on the display panel. The light-transmitting area forms a fixed grating effect, which will cause uneven visual display (mura) in off-screen and bright-screen states, which affects a display performance of the display panel.

### SUMMARY

### Technical Solution

The present application provides a display panel and a display device to solve an issue of poor display performance of the display panel.

In one aspect, the present application provides a display panel comprising:
a base substrate;
a plurality of sub-pixels disposed on the base substrate in an array, wherein each of the sub-pixels comprises a pixel circuit and a light-emitting element, the pixel circuit is configured to drive the light-emitting element, the pixel circuit comprises driving transistors, and the light-emitting element comprises a pixel electrode;
a plurality of first connection parts, wherein each of the first connection parts is connected to one of pixel electrodes and one of the driving transistors, the first connection parts are further configured to connect signal lines, the first connection parts extend along a first direction, adjacent first connection parts are disposed at intervals, and a middle part of one of the first connection parts is provided with a first bending part.

In the display panel of the present application, the first connection parts are serpentine connection parts.

In the display panel of the present application, the first bending part is a bending part having at least one shape of a broken line, a curved line, and an arc.

In the display panel of the present application, the display panel further comprises:
a plurality of second connection parts, wherein each of the second connection parts is connected to one of the pixel electrodes and one of the driving transistors, and adjacent second connection parts are spaced along the first direction to form a first accommodation space;
wherein the second connection parts and the first connection parts are disposed in a dislocation along a second direction, the first direction and the second direction intersect, and the first bending part is located in the first accommodating space.

In the display panel of the present application, a middle part of one of the second connection parts is provided with a second bending part, the adjacent first connection parts are spaced along the first direction to form a second accommodating space, and the second bending part is located in the second accommodating space.

In the display panel of the present application, the one of the first connection parts further comprises two first bending ends, and the first bending ends form a first avoiding space;
wherein one of the second connection parts further comprises two second bending ends, the second bending ends form a second avoiding space, the first bending ends are at least partially located in the second avoiding space, and the second bending ends are at least partially located in the first avoiding space.

In the display panel of the present application, the first connection parts and the second connection parts are made of a transparent conductive material.

In the display panel of the present application, the display panel further comprises:
a plurality of third connection parts, wherein the first connection parts and the third connection parts are disposed in a same layer, each of the third connection parts is connected to one of the pixel electrodes and one of the driving transistors, and the third connection parts are linear and extend along the first direction;
wherein the third connection parts extend along the first direction, adjacent third connection parts are disposed at intervals, and each of the third connection parts is disposed between two adjacent first connection parts.

In the display panel of the present application, one of the first connection parts comprises a first via hole and a second via hole, the one of the first connection parts is connected to the pixel electrode through the first via hole, and the one of the first connection parts is connected to the driving transistor through the second via hole.

In the display panel of the present application, the first via hole and the second via hole are disposed adjacently or at intervals.

In the display panel of the present application, the display panel further comprises a second display area, the first display area and the second display area are disposed adjacently, and the display panel further comprises:
a plurality of fourth connection parts, wherein the fourth connection parts are disposed in the second display area, and each of the fourth connection parts is connected to one of the pixel electrodes and one of the driving transistors;
wherein the fourth connection parts extend along the first direction, adjacent fourth connection parts are disposed at intervals along the first direction, and a middle part of one of the fourth connection parts is provided with a third bending part.

In the display panel of the present application, the display panel comprises a first display area and a fan-out area, the fan-out area overlaps with the first display area, the fan-out area and the second display area are spaced apart, and the first connection parts are located in the first display area.

In the display panel of the present application, the third connection parts extend along the second display area to the first display area in the first direction.

On the other hand, the present application further provides a display device, which includes a display panel, and the display panel includes:
a base substrate;
a plurality of sub-pixels disposed on the base substrate in an array, wherein each of the sub-pixels comprises a pixel circuit and a light-emitting element, the pixel circuit is configured to drive the light-emitting element, the pixel circuit comprises driving transistors, and the light-emitting element comprises a pixel electrode;
a plurality of first connection parts, wherein each of the first connection parts is connected to one of pixel electrodes and one of the driving transistors, the first connection parts are further configured to connect signal lines, the first connection parts extend along a first direction, adjacent first connection parts are disposed at intervals, and a middle part of one of the first connection parts is provided with a first bending part.

In the display device of the present application, the first connection parts are serpentine connection parts, and the first bending part is a bending part having at least one shape of a broken line, a curved line, and an arc.

In the display device of the present application, the display panel further comprises:
a plurality of second connection parts, wherein each of the second connection parts is connected to one of the pixel electrodes and one of the driving transistors, and adjacent second connection parts are spaced along the first direction to form a first accommodation space;
wherein the second connection parts and the first connection parts are disposed in a dislocation along a second direction, the first direction and the second direction intersect, and the first bending part is located in the first accommodating space.

In the display device of the present application, a middle part of one of the second connection parts is provided with a second bending part, the adjacent first connection parts are spaced along the first direction to form a second accommodating space, and the second bending part is located in the second accommodating space;
wherein the first connection parts and the second connection parts are made of a transparent conductive material.

In the display device of the present application, the display panel further comprises:
a plurality of third connection parts, wherein the first connection parts and the third connection parts are disposed in a same layer, each of the third connection parts is connected to one of the pixel electrodes and one of the driving transistors, and the third connection parts are linear and extend along the first direction;
wherein the third connection parts extend along the first direction, adjacent third connection parts are disposed at intervals, and each of the third connection parts is disposed between two adjacent first connection parts.

In the display device of the present application, the display panel further comprises a second display area, the first display area and the second display area are disposed adjacently, and the display panel further comprises:
a plurality of fourth connection parts, wherein the fourth connection parts are disposed in the second display area, and each of the fourth connection parts is connected to one of the pixel electrodes and one of the driving transistors;
wherein the fourth connection parts extend along the first direction, adjacent fourth connection parts are disposed at intervals along the first direction, and a middle part of one of the fourth connection parts is provided with a third bending part.

The present application provides a display panel and a display device. A first connection part for connecting an external signal line is provided between a driving transistor and a pixel electrode, so that each of the first connection parts is connected to one of the pixel electrodes and one of the driving transistors. The first connection parts extend along a first direction, and adjacent first connection parts are arranged at intervals. A middle part of the first connection part is provided with a first bending part, so that a length of each of the first connection part can be increased as much as possible within a unit area. As a result, a distribution area of the first connection part is increased, thereby helping to reduce an amount of light transmission of the display panel. This avoids an issue of a grating effect being formed between the adjacent first connection parts due to a sparse distribution of the first connection parts. Further, a display uniformity of the display panel can be improved, which is beneficial to improve a display performance.

### BRIEF DESCRIPTION OF THE DRAWINGS

The technical solutions and other beneficial effects of the present application will be apparent through the detailed description of the specific embodiments of the present application in conjunction with the accompanying drawings.

FIG. 1 is a schematic top-view structure diagram of a display panel provided by an embodiment of the present application.

FIG. 2 is an enlarged schematic view of the structure at A in FIG. 1 of the present application.

FIG. 3 is a schematic cross-sectional structure diagram of a display panel according to an embodiment of the present application.

FIG. 4 is a schematic top-view structure diagram of a display panel according to another embodiment of the present application.

FIG. 5 is an enlarged schematic view of the structure at B in FIG. 4 of the present application.

FIG. 6 is a schematic structural diagram of each region of a display panel according to an embodiment of the present application.

FIG. 7 is a schematic top-view structure diagram of a display panel according to another embodiment of the present application.

FIG. 8 is an enlarged schematic view of the structure at C in FIG. 7 of the present application.

### DETAILED DESCRIPTION

The technical solutions in the embodiments of the present application will be clearly and completely described below with reference to the accompanying drawings in the embodiments of the present application. Obviously, the described embodiments are only a part of the embodiments of the present application, but not all of the embodiments. Based on the embodiments in the present application, all other embodiments obtained by those skilled in the art without creative work fall within the protection scope of the present application.

In addition, in the description of the present application, “plurality” means two or more, unless otherwise expressly and specifically defined. In this application, unless otherwise expressly specified and limited, a first feature “on” or “under” a second feature may include the first and second features in direct contact or may include the first and second features not directly but through additional features between them. Also, the first feature being “above”, “over” and “on” the second feature includes the first feature being directly above and obliquely above the second feature, or simply means that the first feature is level higher than the second feature. The first feature is “below”, “under” and “underneath” the second feature includes the first feature is directly below and diagonally below the second feature, or simply means that the first feature has a lower level than the second feature. In the description of the present application, “plurality” means two or more, unless otherwise expressly and specifically defined.

The following disclosure provides many different embodiments or examples for implementing different structures of the present application. To simplify the disclosure of the present application, the components and arrangements of specific examples are described below. Of course, they are only examples and are not intended to limit the application. Furthermore, this application may repeat reference numerals and/or reference letters in different instances. This repetition is for the purpose of simplicity and clarity and does not in itself indicate a relationship between the various embodiments and/or arrangements discussed.

Embodiments of the present application provide a display panel and a display device, which will be described in detail below.

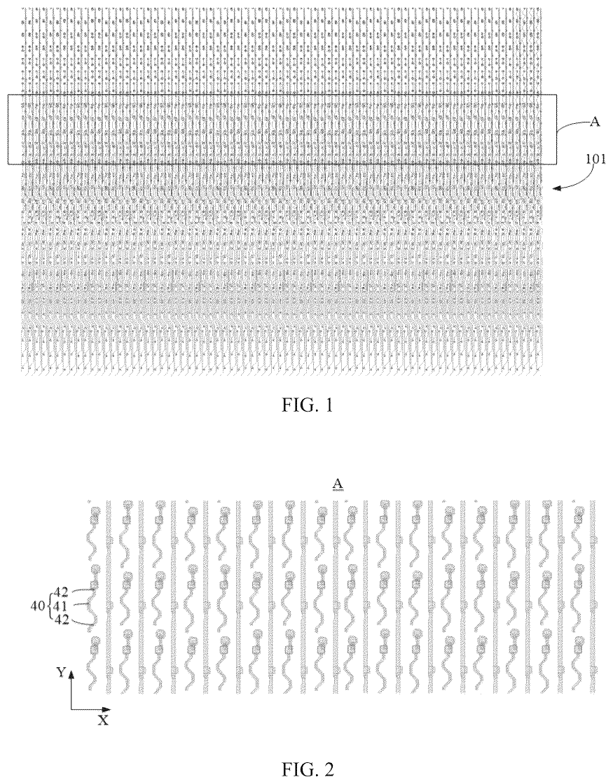

Referring to FIG. 1 to FIG. 8, an embodiment of the present application provides a display panel. The display panel is provided with a plurality of sub-pixels (not shown). At least one sub-pixel includes a pixel circuit (not shown) and a light-emitting element 30.

The pixel circuit is used to drive the connected light-emitting element 30. For example, the pixel circuit is configured to supply a drive current to drive the light emitting element 30 to emit light. The pixel circuit may include a plurality of thin film transistors and at least one capacitor. For example, the pixel circuit may have a 3T1C (3 TFTs and 1 capacitor) structure, a 7T1C (7 TFTs and 1 capacitor) structure, or a 5T1C (5 TFTs and 1 capacitor) structure, and so on. Corresponding scanning signals, light-emitting driving signals, data signals, etc. can be received through the pixel circuit, so as to drive the light-emitting element 30 to emit light. The specific principle of the pixel circuit driving the light-emitting element 30 to emit light is not repeated here.

In an embodiment of the present application, the pixel circuit includes a driving transistor 20, and the light-emitting element 30 includes a pixel electrode 31. The pixel electrode 31 may be an anode of the OLED light-emitting device.

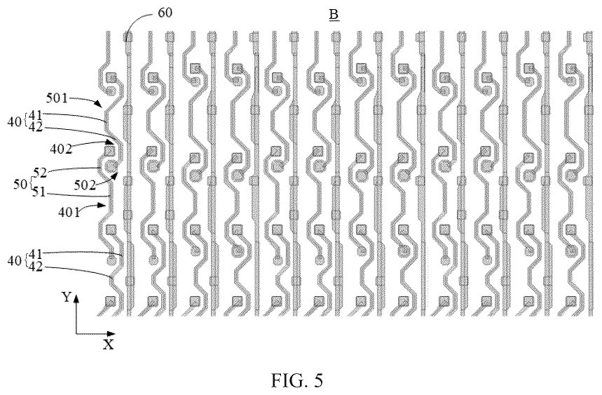

The base substrate 10 may be a flexible base substrate 10 or a rigid base substrate 10. Exemplarily, when the base substrate 10 is a flexible base substrate 10, a material of the base substrate 10 may be polyimide (PI), polyethylene naphthalate (PEN), thermoplastic polyester (PET), etc. When the base substrate 10 is a rigid base substrate 10, the base substrate 10 may be a rigid material such as glass and quartz. Taking the base substrate 10 as a PI substrate as an example, the base substrate 10 may adopt a single-layer PI structure, and the base substrate 10 may also adopt a double-layer PI structure. As shown in FIG. 4, the base substrate 10 includes a first PI substrate 11, a first buffer layer 12, a second PI substrate 13, and a second buffer layer 14, which are sequentially arranged from bottom to top along its thickness direction.

A plurality of driving transistors 20 are arrayed on the base substrate 10. A plurality of pixel electrodes 31 are disposed on the driving transistor 20. In this embodiment, the display panel is an OLED display panel as an example. Correspondingly, the light-emitting element 30 may be an organic light-emitting diode (OLED). The light-emitting element 30 emits red light, green light, blue light, or white light, etc. Under the driving of its corresponding pixel circuit, the color of light emitted by the light-emitting element 30 can be determined as required. The pixel electrode 31 in the embodiment of the present application may be an anode of the light-emitting element 30. Specifically, the light-emitting element 30 may include an anode, a cathode, and a light-emitting functional layer between the anode and the cathode. The anode of the light-emitting element 30 may be electrically connected to the driving transistor 20 in the corresponding pixel circuit. It should be noted that, in the display panel, in addition to the light-emitting functional layer, film layers such as an encapsulation layer, a touch layer, a polarizing layer, and a cover plate may also be provided on the pixel electrode 31.

Each of the first connection parts 40 is connected to one pixel electrode 31 and one driving transistor 20. Specifically, the driving transistor 20 includes an active layer 21, a gate layer 22, and a source and drain layer 23 in sequence from top to bottom along the thickness direction of the base substrate 10. The active layer 21 is disposed on one side of the base substrate 10, and the gate layer 22 is disposed on the active layer 21. The source and drain layer 23 is disposed on the gate layer 212. The active layer 21, the gate layer 22, and the source and drain layer 23 are insulated from each other. The first connection part 40 is connected between the source and drain layer 23 and the pixel electrode 31. Specifically, the first connection part 40 may be connected to the source in the source and drain layer 23. A bridge layer 24 may also be disposed between the first connection part 40 and the source and drain layer 23. The material of the bridge layer 24 may be the same as that of the source and drain layer 23. The bridge layer 24 can be used to connect a voltage signal line VDD, so as to increase the number of connections between the driving transistor 20 and the signal line VDD, thereby enhancing a display driving capability.

The first connection parts 40 extend along the first direction Y, and the first connection parts 40 are arranged in an array corresponding to the sub-pixels on the display panel. Specifically, the first connection parts 40 can be arranged in multiple rows along the first direction Y and arranged in multiple rows along the second direction X, for example. The first connection parts 40 arranged in a row along the second direction X can be referred to as the first connection parts 40 in the same row, and the first connection parts 40 arranged in a row in the first direction Y can be referred to as the first connection parts 40 in the same column. The first connection parts 40 are used to connect signal lines, for example, the first connection parts 40 in the same column may be electrically connected to one voltage signal line VDD. The first direction Y may be a vertical direction parallel to the display plane of the display panel, and the second direction X may be a horizontal direction parallel to the display plane of the display panel.

The plurality of first connection parts 40 extending along the first direction Y are arranged along the second direction X at intervals. Adjacent first connection parts 40 are arranged at intervals, and a first bending part 41 is disposed in a middle part of the first connection parts 40. The first bending part 41 is used to increase the length of the first bending part 41.

In the display panel of the embodiment of the present application, the first connection parts 40 for connecting external signal lines are provided between the driving transistor 20 and the pixel electrode 31, so that each first connection part 40 is connected to one pixel electrode 31 and one driving transistor 20. The first connection parts 40 extend along the first direction Y, and adjacent first connection parts 40 are arranged at intervals. A first bending part 41 is provided in a middle part of the first connection part 40, so that the length of each first connection part 40 can be increased as much as possible within a unit area. As a result, the distribution area of the first connection part 40 is increased, which is beneficial to reduce the amount of light transmission of the display panel. This avoids light leakage and avoids the issue of grating effect between adjacent first connection parts 40 due to too sparse distribution of the first connection parts 40, thereby improving a display uniformity of the display panel and improving a display performance.

In some embodiments, the first connection part 40 is a serpentine connection part. Specifically, it may be a connection part formed by an S-shaped curve. That is, when the first connection part 40 forms a wiring, it may be a serpentine winding. By arranging the first connection part 40 with a serpentine connection part, the length of the first connection part 40 in the first direction Y can be increased. This can increase a compactness of the structure of the first connection part 40, thereby helping to improve a distribution density of the first connection part 40. This can better avoid issues such as light leakage and grating effect, which is beneficial to further improve a display uniformity of the display panel.

In some embodiments, as shown in FIG. 5, the first connection part 40 further includes two first bending ends 42. The first bending end 42 forms a first avoiding space 402. The second connection part 50 further includes two second bending ends 52. The second bending end 52 forms a second avoiding space 502. The first bending end 42 is at least partially located in the second avoiding space 502. The second bending end 52 is at least partially located in the first avoiding space 402. The arrangement of the first avoiding space 402 and the second avoiding space 502 is beneficial to improve the compactness of the structure between the first connection part 40 and the second connection part 50. Thus, the distribution density of the first connection part 40 and the second connection part 50 is increased. This can better avoid issues such as light leakage and grating effect, which is beneficial to further improve the display uniformity of the display panel.

In some embodiments, as shown in FIG. 4 and FIG. 5, the display panel further includes a plurality of second connection parts 50. The second connection parts 50 can also be arranged in an array. For example, it can be arranged in multiple rows along the first direction Y and arranged in multiple rows along the second direction X. Each of the second connection parts 50 is connected to one pixel electrode 31 and one driving transistor 20. Adjacent second connection parts 50 are spaced along the first direction Y to form first accommodating spaces 501. The first bending part 41 is located in the first accommodating space 501. The second connection part 50 and the first connection part 40 are arranged in a dislocation along the second direction X. Specifically, the first connection part 40 and the second connection part 50 may be arranged in parallel. The functions of the first connection part 40 and the second connection part 50 are the same. The first connection part 40 and the second connection part 50 are only different in shape. Specifically, the bending directions of the first bending part 41 and the second bending part 51 are opposite. The first accommodating space 501 provides the first bending part 41 with a sufficiently large bending winding space, so that the first bending part 41 can form a longer bending length in the first accommodating space 501. This allows the first bending parts 41 to be distributed in the first accommodating space 501 as much as possible, thereby increasing the distribution area of the second connection parts 50. Therefore, it is beneficial to reduce the light transmittance of the display panel, avoid light leakage, and avoid the grating effect between the adjacent second connection portions 50 due to the sparse distribution of the second connection parts 50, thereby improving the display uniformity of the display panel.

The first direction Y and the second direction X intersect. The first direction Y and the second direction X may be set parallel to the same display plane of the display panel. Specifically, in this embodiment, the first direction Y and the second direction X may be directions perpendicular to each other. The first direction Y may be a vertical direction, and the second direction X may be a horizontal direction. In addition, parallel means the state which the angle formed by two straight lines is −10 degrees or more and 10 degrees or less. Therefore, the state where this angle is −5° or more and 5° or less is also included. In addition, “perpendicular” refers to a state in which the angle formed by two straight lines is 80° or more and 100° or less. Therefore, the state of the angle of 85° or more and 95° or less is also included.

In some embodiments, a middle part of the second connection part 50 is provided with a second bending part 51. The bending directions of the first bending part 41 and the second bending part 51 are opposite. Adjacent first connection parts 40 are spaced along the first direction Y to form second accommodating spaces 401. The second bending part 51 is located in the second accommodating space 401. In this embodiment of the present application, the second accommodating space 401 is used to increase a sufficiently large bending and winding space for the second bending part 51, so that the second bending part 51 can form a longer bending length in the second accommodating space 401. This allows the second bending parts 51 to be distributed in the second accommodating space 401 as much as possible. Therefore, on the basis of the first accommodating space 501 and the first bending part 41, the structure compactness between the second connection part 50 and the second connection part 50 is further improved. This can better avoid issues such as light leakage and grating effect, which is beneficial to further improve the display uniformity of the display panel.

In some embodiments, the first bending part 41 and the second bending part 51 may be bending parts having at least one shape of a broken line, a curved line and an arc. For example, the second bending part 51 may be a bending part formed of only any one of a folded line, a curved line, and an arc. The second bending part 51 may be a bending part formed by two shapes of a folded line and a curved line, or the like. Exemplarily, the second bending part 51 may be in a zigzag shape composed of continuous multiple segments of broken lines or may be in the shape of a wavy line composed of multiple segments of continuous curved lines. This embodiment does not specifically limit the shape of the second bending part 51.

In some embodiments, the first connection part 40 and the second connection part 50 are made of transparent conductive material. Specifically, both the first connection part 40 and the second connection part 50 may use indium tin oxide (ITO), indium zinc oxide (IZO), indium gallium zinc oxide (IGZO) in any one or several forms. Because the grating effect of the transparent conductive material is small, the first connection part 40 and the second connection part 50 are also made of transparent conductive material. Therefore, the grating effect of the first connection part 40 and the second connection part 50 made of metal can be effectively reduced, which is beneficial to further improve the display effect of the display panel.

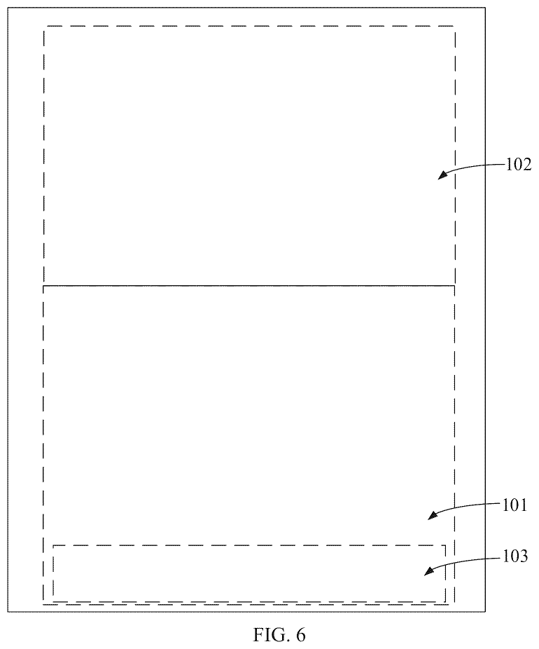

In some embodiments, as shown in FIG. 6, the display panel includes a first display area 101 and a fan-out area 103. The fan-out area 103 coincides with the first display area 101. Specifically, the fan-out area 103 partially overlaps with the first display area 101. That is, the first display area 101 includes the fan-out area 103. The first connection part 40 is located in the first display area 101. That is, the first connection part 40 is also located in the fan-out area 103.

The first display area 101 is an area in the display panel where an image is actually displayed. The fan-out area 103 refers to an area where a plurality of data lines of the display panel are gathered in a fan shape. One end of the fan-out area 103 is electrically connected to a plurality of data lines of the display panel, and one end is electrically connected to the gate driving circuit, so that the gate driving circuit can realize progressive scan driving. Generally, the fan-out area 103 is located in the non-display area of the display panel, which is not conducive to the realization of a narrow frame or no frame of the display panel. When the fan-out area 103 coincides with the first display area 101 (Fanout in AA, FIAA), that is, along the thickness direction of the display panel, the fan-out area 103 is located below the first display area 101. The sub-pixels used for display in the fan-out area 103 are compressed. That is, by reducing the size of the switching device and the distribution of the wiring width, a part of the space is used for wirings such as data lines connected to the fan-out area 103. Thus, the fan-out area 103 can be multiplexed as an area for displaying images. Exemplarily, the fan-out area 103 may be provided in the same layer as the gate driving circuit or may be provided in a different layer with the gate driving circuit. As long as the fan-out area 103 is located below the first display area 101, there is no specific limitation. By setting the fan-out area 103 to overlap with the first display area 101, the non-display area of the display panel is further reduced or eliminated, which is beneficial to the realization of a narrow border or no border of the display panel. In addition, since the sub-pixels in the fan-out area 103 are partially routed due to the size compression of the switching devices and metal wirings, especially the wirings of the first connection part 40 are relatively sparse, the horizontal direction in the off-screen and bright-screen states is sparse. Depending on the display uneven phenomenon. Therefore, by arranging the first connection part 40 in the fan-out area 103, it is also beneficial to improve the uniformity of the display of the fan-out area 103.

The shape of the first display area 101 may be various. Exemplarily, the first display area 101 may be a rectangle, such as a rectangle with rounded corners. The first display area 101 may also be circular or oval. It is understood that the first display area 101 may also be in other shapes such as a rectangle, a semicircle, and a pentagon. This embodiment does not specifically limit this.

In some embodiments, the display panel further includes a second display area 102. The first display area 101 and the second display area 102 are arranged adjacent to each other. The second display area 102 is an area in the display panel where an image is actually displayed. Relative to the first display area 101, the second display area 102 is a conventional display area, that is, the second display area 102 does not overlap with the fan-out area 103. Specifically, the first display area 101 may be located at the top middle position of the display panel. The second display area 102 may surround the first display area 101. However, this embodiment does not limit this. Exemplarily, the first display area 101 may be located at other positions such as the upper left corner or the upper right corner of the display panel, or the second display area 102 may surround at least one side of the first display area 101. The shape of the second display area 102 may be various. Exemplarily, the second display area 102 may be a rectangle, such as a rectangle with rounded corners. The second display area 102 may also be circular or oval. It is understood that the second display area 102 may also be in other shapes such as a rectangle, a semicircle, a pentagon, and the like. This embodiment does not specifically limit this.

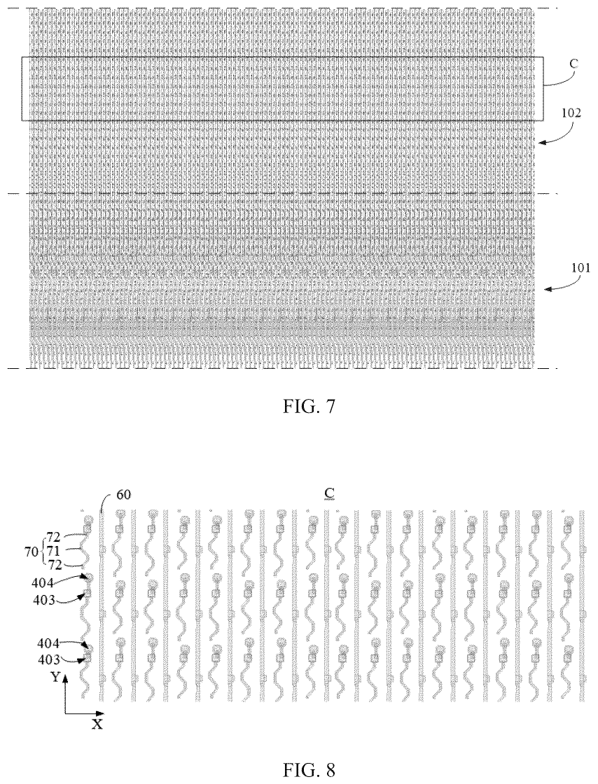

In some embodiments, as shown in FIG. 7 and FIG. 8, the display panel further includes a plurality of third connection parts 60. The main difference between the first connection part 40 and the third connection part 60 lies in the distribution shape.

The third connection portion 60 is located in at least one of the first display area 101, the fan-out area 103, and the second display area 102. The first connection part 40 and the third connection part 60 are provided on the same layer. Each of the third connection parts 60 is connected to one pixel electrode 31 and one driving transistor 20. The third connection part 60 is linear and extends along the first direction Y. Exemplarily, the third connection part 60 may extend in the first direction Y along the second display area 102, the fan-out area 103, and the first display area 101 in sequence, or the third connection part 60 may only extend along the first direction Y within the fan-out area 103. Adjacent third connection parts 60 are arranged along the second direction X at intervals. Each third connection part 60 is disposed between two adjacent first connection parts 40. The first connection part 40 and the third connection part 60 are disposed on the same layer, and both the first connection part 40 and the third connection part 60 are connection parts for electrical connection. Therefore, providing the third connection part 60 on the basis of the first connection part 40 can improve the compactness of the structure between the first connection part 40 and the second connection part 50. This is beneficial to increase the metal area of the film layer where the first connection part 40 and the third connection part 60 are located. By increasing the distribution density, issues such as light leakage and grating effects can be further avoided.

Please continue to refer to FIG. 8, the display panel further includes a plurality of fourth connection parts 70. The fourth connection part 70 is disposed in the second display area 102. The fourth connection parts 70 may also be arranged in an array, for example, may be arranged in multiple rows along the first direction Y, and may be arranged in multiple rows along the second direction X. Each of the fourth connection parts 70 is connected to one pixel electrode 31 and one driving transistor 20. The fourth connection part 70 extends along the first direction Y. The adjacent fourth connection parts 70 are arranged at intervals along the first direction Y. A third bending part 71 is provided in the middle part of the fourth connection part 70. The end of the fourth connection part 70 is formed with a fourth bending part 72.

In the second display area 102, the middle part of the fourth connection part 70 is set as a bending part, so as to increase the length of each first connection part 40 as much as possible within a unit area. As a result, the distribution area of the fourth connection part 70 is increased, thereby helping to reduce the amount of light transmitted through the second display area 102 of the display panel. To avoid light leakage and to avoid the issue of grating effect between adjacent fourth connection parts 70 caused by too sparse distribution of the fourth connection parts 70. Further, the display uniformity of the first display area 101 and the second display area 102 in the display panel can be improved, which is beneficial to further improve the overall display performance of the display panel.

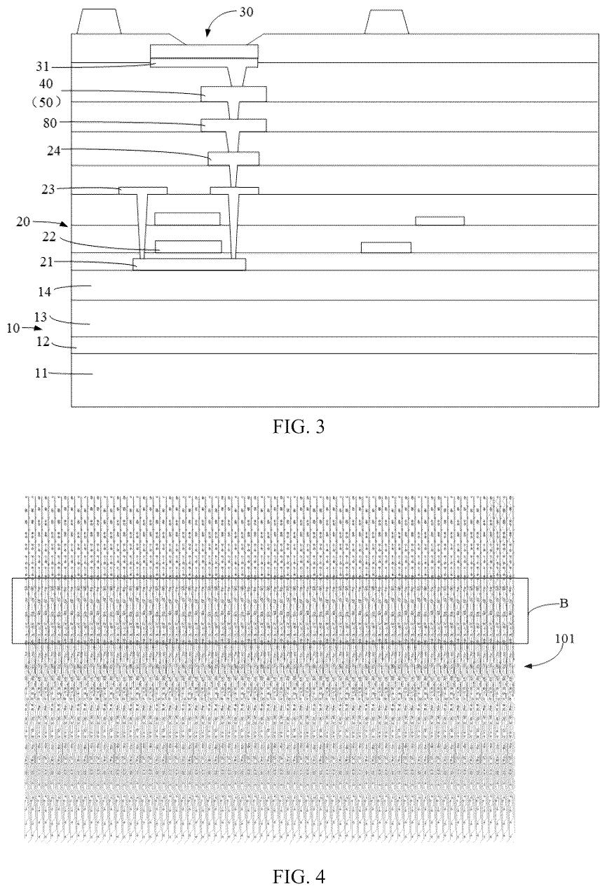

In some embodiments, as shown in FIG. 3, the display panel may further include a plurality of fifth connection parts 80. The plurality of fifth connection parts 80 may also be arranged in an array, for example, they may be arranged in multiple rows along the first direction Y, and may be arranged in multiple rows along the second direction X. The fifth connection part 80 is located in the first display area 101. Each fifth connection part 80 is connected between a pixel electrode 31 and a first connection part 40. Alternatively, each fifth connection part 80 is connected between a pixel electrode 31 and a second connection part 50. The fifth connection part 80 can be used to connect the voltage signal line VDD, so as to increase the number of connections between the driving transistor 20 and the signal line VDD, thereby enhancing the display driving capability.

In some embodiments, the first connection part 40 includes a first via hole 403 and a second via hole 404. As shown in FIG. 8, the first connection part 40 is connected to the pixel electrode 31 through the first via hole 403, and the first connection part 40 is connected to the driving transistor 20 through the second via hole 404. The first via hole 403 and the second via hole 404 may be disposed adjacent to each other. Alternatively, the first via hole 403 and the second via hole 404 may also be arranged at intervals. The length of the distance between the first via hole 403 and the second via hole 404 on the base substrate 10 also affects the length of the fifth connection part 80. Specifically, the longer the distance between the first via hole 403 and the second via hole 404 is, the longer the line length of the fifth connection part 80 is. The shorter the distance between the first via hole 403 and the second via hole 404 on the base substrate 10 is, the shorter the line length of the fifth connection part 80 is. Therefore, the via position distance between the first via hole 403 and the second via hole 404 is adjusted according to the actual length of the fifth connection part 80. This is beneficial to improve the flexibility of the first connection part 40 to realize connection. Exemplarily, by setting the distances between the first via hole 403 and the second via hole 404 on the first connection part 40 in each row to be the same, the distribution of the area of the fifth connection part 80 can be set to have regularity. Thereby, it can be prevented from being in the disposition area of the fifth connection part 80. The areas of the fifth connection parts 80 are different, which leads to the continuous reflection of light, resulting in different brightness of the sub-pixels above the different fifth connection parts 80. This results in a noticeable sudden change in the display brightness somewhere. That is, by controlling the distribution density of the fifth connection part 80, the display area where the fifth connection part 80 is located plays a role of transition of the display performance. In this way, the issue of uneven display caused by the arrangement of the fifth connection part 80 is reduced.

The connection relationship between the third connection part 60 and the first connection part 40 is the same, so the first via hole 403 and the second via hole 404 can also be disposed on the third connection part 60, which can have the same effect, which will not be repeated here.

It should be noted that, the third connection part 60, the fourth connection part 70, and the fifth connection part 80 can also be made of transparent conductive materials. Specifically, indium tin oxide (ITO), indium zinc oxide (IZO), indium gallium zinc oxide (IGZO) can be used for any one or several forms of the third connection part 60, the fourth connection part 70, and the fifth connection part 80. The materials of the first connection part 40, the second connection part 50, the third connection part 60, the fourth connection part 70, and the fifth connection part 80 may be the same or different, which are not specifically limited herein.

The present application also provides a display device. The display device includes the above-mentioned display panel. In the display panel of the display device according to the embodiment of the present application, the first connection parts 40 for connecting external signal lines are provided between the driving transistor 20 and the pixel electrodes 31, so that each first connection part 40 is connected to one pixel electrode 31 and one driving transistor 20. The first connection parts 40 extend along the first direction Y, and adjacent first connection parts 40 are arranged at intervals. A first bending part 41 is provided in the middle part of the first connection part 40, so that the length of each first connection part 40 can be increased as much as possible within a unit area. As a result, the distribution area of the first connection part 40 is increased, which is beneficial to reduce the amount of light transmission of the display panel. To avoid light leakage and to avoid the issue of grating effect between adjacent first connection parts 40 due to too sparse distribution of the first connection parts 40, the display uniformity of the display panel can be improved, and the display performance can be improved.

Since the display device has the above-mentioned display panel, it has all the same beneficial effects, which will not be repeated in this embodiment. The embodiments of the present application do not specifically limit the application of the display device. It can be any product or part with display function such as TV, laptop, tablet, wearable display device (such as smart bracelet, smart watch, etc.), mobile phone, virtual reality device, augmented reality device, car display, advertising light box, etc.

In the above embodiments, the description of each embodiment has its own emphasis. For parts that are not described in detail in a certain embodiment, reference may be made to related descriptions of other embodiments.

During specific implementation, each of the above units or structures may be implemented as independent entities. It can also be combined arbitrarily and implemented as the same or several entities. For the specific implementation of the above units or structures, reference may be made to the foregoing method embodiments, and details are not described herein again.

The display panel and the display device provided by the embodiments of the present application are described in detail above. Specific examples are used herein to illustrate the principles and implementations of the embodiments of the present application. The descriptions of the above embodiments are only used to help understand the technical solutions and core ideas of the embodiments of the present application. Those of ordinary skill in the art should understand that the technical solutions described in the foregoing embodiments can still be modified, or equivalently replace some of the technical features. However, these modifications or substitutions do not make the essence of the corresponding technical solutions deviate from the scope of the technical solutions of the embodiments of the present application.

What is claimed is:

1. A display panel, comprising:
a base substrate;
a plurality of sub-pixels disposed on the base substrate in an array, wherein each of the sub-pixels comprises a pixel circuit and a light-emitting element, the pixel circuit is configured to drive the light-emitting element, the pixel circuit comprises driving transistors, and the light-emitting element comprises a pixel electrode;
a plurality of first connection parts, wherein each of the first connection parts is connected to one of pixel electrodes and one of the driving transistors, the first connection parts are further configured to connect signal lines, the first connection parts extend along a first direction, adjacent first connection parts are disposed at intervals, and a middle part of one of the first connection parts is provided with a first bending part.

2. The display panel of claim 1, wherein the first connection parts are serpentine connection parts.

3. The display panel of claim 2, wherein the first bending part is a bending part having at least one shape of a broken line, a curved line, and an arc.

4. The display panel of claim 1, wherein the display panel further comprises:
a plurality of second connection parts, wherein each of the second connection parts is connected to one of the pixel electrodes and one of the driving transistors, and adjacent second connection parts are spaced along the first direction to form a first accommodation space;
wherein the second connection parts and the first connection parts are disposed in a dislocation along a second direction, the first direction and the second direction intersect, and the first bending part is located in the first accommodating space.

5. The display panel of claim 4, wherein a middle part of one of the second connection parts is provided with a second bending part, the adjacent first connection parts are spaced along the first direction to form a second accommodating space, and the second bending part is located in the second accommodating space.

6. The display panel of claim 4, wherein the one of the first connection parts further comprises two first bending ends, and the first bending ends form a first avoiding space;
wherein one of the second connection parts further comprises two second bending ends, the second bending ends form a second avoiding space, the first bending ends are at least partially located in the second avoiding space, and the second bending ends are at least partially located in the first avoiding space.

7. The display panel of claim 4, wherein the first connection parts and the second connection parts are made of a transparent conductive material.

8. The display panel of claim 1, wherein the driving transistor comprises:
an active layer disposed on one side of the base substrate;
a gate layer disposed on the active layer; and
a source and drain layer disposed on the gate layer, wherein the first connection parts are connected between the source and drain layer and the pixel electrode.

9. The display panel of claim 1, wherein the display panel further comprises:
a plurality of third connection parts, wherein the first connection parts and the third connection parts are disposed in a same layer, each of the third connection parts is connected to one of the pixel electrodes and one of the driving transistors, and the third connection parts are linear and extend along the first direction;
wherein the third connection parts extend along the first direction, adjacent third connection parts are disposed at intervals, and each of the third connection parts is disposed between two adjacent first connection parts.

10. The display panel of claim 1, wherein one of the first connection parts comprises a first via hole and a second via hole, the one of the first connection parts is connected to the pixel electrode through the first via hole, and the one of the first connection parts is connected to the driving transistor through the second via hole.

11. The display panel of claim 10, wherein the first via hole and the second via hole are disposed adjacently or at intervals.

12. The display panel of claim 1, wherein the display panel comprises a first display area and a fan-out area, the fan-out area overlaps with the first display area, the fan-out area and the second display area are spaced apart, and the first connection parts are located in the first display area.

13. The display panel of claim 12, wherein the display panel further comprises a second display area, the first display area and the second display area are disposed adjacently, and the display panel further comprises:
a plurality of fourth connection parts, wherein the fourth connection parts are disposed in the second display area, and each of the fourth connection parts is connected to one of the pixel electrodes and one of the driving transistors;
wherein the fourth connection parts extend along the first direction, adjacent fourth connection parts are disposed at intervals along the first direction, and a middle part of one of the fourth connection parts is provided with a third bending part.

14. The display panel of claim 13, wherein the third connection parts extend along the second display area to the first display area in the first direction.

15. A display device comprising a display panel, the display panel comprising:
a base substrate;
a plurality of sub-pixels disposed on the base substrate in an array, wherein each of the sub-pixels comprises a pixel circuit and a light-emitting element, the pixel circuit is configured to drive the light-emitting element, the pixel circuit comprises driving transistors, and the light-emitting element comprises a pixel electrode;
a plurality of first connection parts, wherein each of the first connection parts is connected to one of pixel electrodes and one of the driving transistors, the first connection parts are further configured to connect signal lines, the first connection parts extend along a first direction, adjacent first connection parts are disposed at intervals, and a middle part of one of the first connection parts is provided with a first bending part.

16. The display device of claim 15, wherein the first connection parts are serpentine connection parts, and the first bending part is a bending part having at least one shape of a broken line, a curved line, and an arc.

17. The display device of claim 15, wherein the display panel further comprises:
a plurality of second connection parts, wherein each of the second connection parts is connected to one of the pixel electrodes and one of the driving transistors, and adjacent second connection parts are spaced along the first direction to form a first accommodation space;
wherein the second connection parts and the first connection parts are disposed in a dislocation along a second direction, the first direction and the second direction intersect, and the first bending part is located in the first accommodating space.

18. The display device of claim 17, wherein a middle part of one of the second connection parts is provided with a second bending part, the adjacent first connection parts are spaced along the first direction to form a second accommodating space, and the second bending part is located in the second accommodating space;
wherein the first connection parts and the second connection parts are made of a transparent conductive material.

19. The display device of claim 18, wherein the display panel further comprises:
a plurality of third connection parts, wherein the first connection parts and the third connection parts are disposed in a same layer, each of the third connection parts is connected to one of the pixel electrodes and one of the driving transistors, and the third connection parts are linear and extend along the first direction;
wherein the third connection parts extend along the first direction, adjacent third connection parts are disposed at intervals, and each of the third connection parts is disposed between two adjacent first connection parts.

20. The display device of claim 19, wherein the display panel further comprises a second display area, the first display area and the second display area are disposed adjacently, and the display panel further comprises:
a plurality of fourth connection parts, wherein the fourth connection parts are disposed in the second display area, and each of the fourth connection parts is connected to one of the pixel electrodes and one of the driving transistors;
wherein the fourth connection parts extend along the first direction, adjacent fourth connection parts are disposed at intervals along the first direction, and a middle part of one of the fourth connection parts is provided with a third bending part.
